(19) United States
(12) Patent Application Publication
(10) Pub. No.: US 2007/0253173 A1
(43) Pub. Date: Nov. 1, 2007

(54) Motion Sensor and Secure Portable Container Incorporating Same

(76) Inventor: Ernst Antony Dart, Tannum Sands (AU)

Correspondence Address: VINSON & ELKINS, L.L.P., 1001 FANNIN STREET, 2300 FIRST CITY TOWER, HOUSTON, TX, 77002-6760, US

(21) Appl. No.: 11/624,584

(22) Filed: Jan. 18, 2007

Related U.S. Application Data
(60) Provisional application No. 60/760,697, filed on Jan. 20, 2006.

(51) Int. Cl. H05K 1/00

(52) U.S. Cl. 361/736

(57) ABSTRACT

Motion sensor apparatus includes opposing motion detector assemblies that include rolling ball electrical connectors oriented to operate when the device is inverted.

### CROSS-REFERENCE TO RELATED APPLICATIONS

This application claims benefit of priority to U.S. Provisional Application Ser. No. 60/760,698, filed Jan. 20, 2006, the entire contents of which are incorporated herein by reference.

### STATEMENT REGARDING FEDERALLY SPONSORED RESEARCH OR DEVELOPMENT

N/A

### BACKGROUND OF THE INVENTION

It is frequently necessary and/or desirable to detect movement of an object for purposes such as deterring theft or tampering. This may be achieved by integrating an apparatus for detecting movement with an object to be monitored. Typically, the apparatus includes one or more motion sensors and an alerting means and may be attached to and/or co-located with the object to be monitored. The alerting means is activated to provide an indication of detected movement of the object.

Motion sensors generally incorporate mercury switches or similar mechanisms that provide an electrical connection when mercury is displaced to one end of the mercury switch. However, such switches require selective positioning to change state (i.e., from an activated to a de-activated state, or vice versa) in response to certain movements. It is generally necessary that mercury switches be carefully positioned to obtain a desired level of sensitivity for a particular orientation.

A further disadvantage associated with mercury switches is that a stable state may be reached after activation of the switch due to an external stimulus such as movement or an impact. In certain cases, it is desirable to deactivate the alerting means after a defined duration (e.g., for purposes of avoiding a continuously sounding alarm). If the mercury switch is in a stable state (e.g., the mercury disposed at the lower end of a cavity), further movement or impact may not result in re-activation of the alerting means and the monitored object may thus be vulnerable to theft or tampering.

Accordingly, a need exists for an improved motion sensor that overcomes, or at least ameliorates, one or more disadvantages associated with existing arrangements. A need also exists for an apparatus that is capable of detecting movement of an object with which the apparatus is co-located and of providing an alert when such movement is detected.

### SUMMARY

An aspect of the present invention provides a device for sensing motion that includes a race in which a plurality of electrically conductive elements disposed on a surface within the race, and a connecting member sized to move freely within the race in response to gravitational forces and to disturbances in the position or movement of the device. The connecting member is sized such that when at rest on the surface of the race that includes electrically conductive elements, the connected member forms an electrical connection between at least two of the electrically conductive elements.

The race provides an unobstructed path for the connecting member and can be of various configurations, including a continuous loop or oval. The connecting member can be of any shape to roll or move freely through the race such as a sphere or a shape in which at least one sectional plane of the member is a circle, such as a wheel, and can include one or more steel balls. The conductive element can also be made of other conductive materials known in the art including various precious metals such as gold or may be plated with a conductive material such as gold plating. In certain embodiments, the electrically conductive elements include electrically conductive etched portions on a printed circuit board (PCB).

Another aspect of the present disclosure provides a motion sensor including a central planar member that can be a printed circuit board, for example, with a race containing the conductive elements on each side of the board. In this embodiment, one conductive member or ball is contained in each race so at least one ball contacts the conductive members when the device is in either up or down position. The races in this case are enclosed at the top and when a particular ball is in the “up side down” position, that ball does not contact the electrical conductors, but the opposing ball does. When the device is flipped over, the opposite applies so the device is operative in either orientation.

Certain devices further include a pair of covers each mounted on a side of the central planar member, providing the races. The central planar member is, therefore, in certain embodiments, a double-sided printed circuit board (PCB) with etched conductors.

In certain embodiments that include two balls or conductive members as described above, the device includes two parallel printed circuit boards spaced apart and the races and conductors as described are between the circuit boards in a side by side arrangement. The boards are spaced so there is a gap above the ball when the ball is contained in the race. In this way, when one ball is in the active orientation and is in contact with the conductors, the opposing ball is resting on the top of the race and is not in contact with the conductors. Flipping the device over, reverses this orientation. This embodiment can also include devices in which the board includes depressions formed in the board to form the bottom of the races in order to provide a thinner device. The devices as described can further include at least one spacer disposed between the PCBs to define at least a part of one or more races

The devices as described include an electronic controller electrically coupled to the electrically conductive elements. Each set of conductive elements in a particular race define the two sides of a circuit such that adjacent elements are on opposite sides of the circuit. In that way, when the ball contacts two adjacent elements the circuit is completed and can be detected by the controller. As the ball moves across the elements, breaking and completing individual circuits, this movement is detected by the controller. The controller is configured to activate an alarm in response to a predetermined set of electrical signals that indicate certain types of motion of the device. The controller can be programmed for example, to accommodate slight jarring motions and to sound the alarm only upon sustained or continuous motion such as would occur should the device be picked up and carried.

Throughout this disclosure, unless the context dictates otherwise, the word “comprise” or variations such as “comprises” or “comprising,” is understood to mean “includes, but is not limited to” such that other elements that are not explicitly mentioned may also be included. Further, unless the context dictates otherwise, use of the term “a” may mean a singular object or element, or it may mean a plurality, or one or more of such objects or elements.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein.

FIG. 1A is a top view of a printed circuit board for a motion sensor.
FIG. 1B is a perspective view of the printed circuit board of FIG. 1A.

FIG. 2A is a top view of a cover for a motion sensor.

FIG. 2B is a sectional front view of the cover of FIG. 2A, taken across the section ‘A-A’ as shown in FIG. 2A.

FIG. 3 is an exploded sectional front elevation of a motion sensor assembly including two conductive balls.

FIG. 4A is a sectional front view of a motion sensor assembly taken across the section ‘C-C’ as shown in FIG. 4B.

FIG. 4B is a sectional top view of the motion sensor assembly taken across the section ‘B-B’ in FIG. 4A.

FIG. 5 is a perspective view of an alternate embodiment of a motion sensor.

FIG. 6 is an exploded perspective view of an alternative embodiment of a motion sensor assembly.

FIG. 7 is a perspective view of a secure portable container that incorporates a motion sensor.

FIG. 8 is a perspective view of the underside of a lid of the portable secure container of FIG. 7.

FIG. 9A is a top view of a PCB used to construct the motion sensor assembly of FIG. 9C.

FIG. 9B is a top view of a PCB, complementary to the PCB of FIG. 9A, used to construct the motion sensor assembly of FIG. 9C.

FIG. 9C is a sectional view of an another motion sensor assembly.

FIG. 10 is another embodiment of a motion sensor assembly.

### DETAILED DESCRIPTION

Motion sensors as described herein include at least one race and at least one connecting member contained in the race and able to freely move through the race in response to an impact to or variations in orientation of the motion sensor. The races include a plurality of electrically conductive elements electrically coupled to an electronic controller that detects changes in the electrical connections as the connector moves in the race, and signals an alarm or other indication of motion.

Embodiments described hereinafter include one or more races in a circular or linear shape or pattern. However, it is not intended that the invention be limited in this manner as numerous simple and complex race patterns can be practiced. For example, the shape or pattern of the race may be oval, ellipse, or may include a complex configuration of curves and/or other shapes.

Certain embodiments include one or more electrically conductive balls (e.g., from a ball bearing) as connecting members for connecting electrically conductive elements during traversal of the race. However, it is not intended that the invention be limited in this manner as numerous other forms of connecting member can be utilized. For example, the connecting member/s may be in the form of a roller, a bogie or a carriage for traversing the race.

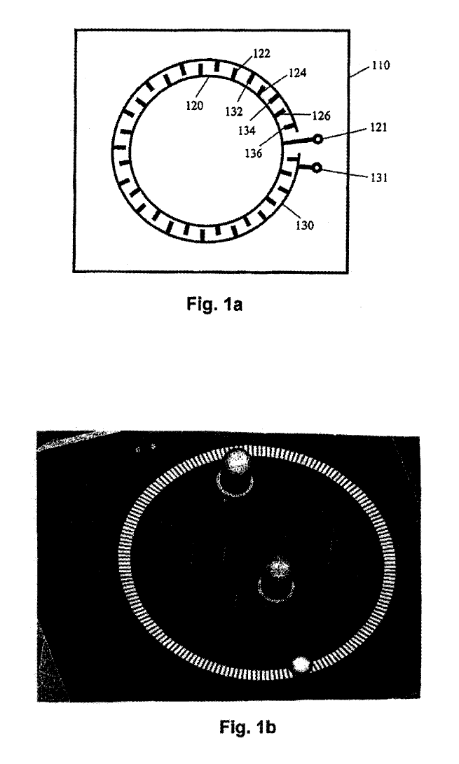

FIGS. 1A and 1B show a top view and a perspective view, respectively, of a printed circuit board (PCB) 110 for a motion sensor. The PCB 110 includes two concentric circular patterns 120 and 130 of etched metal (e.g. copper) portions disposed on a planar surface of the PCB 110 and produced by a conventional PCB etching process. The inner circular pattern 120 includes a number of electrically conductive elements or fingers 122, 124, 126 . . . that are electrically connected to each other and extend radially outwards towards the outer circular pattern 130. The outer circular pattern 130 includes a number of electrically conductive fingers 132, 134, 136 . . . that are electrically connected to each other and extend radially inwards towards the inner circular pattern 120. The electrically conductive fingers 122, 124, 126 . . . of the inner circular pattern 120 are alternately interleaved or interdigitated with the electrically conductive fingers 132, 134, 136 . . . of the outer circular pattern 130. The inner and outer circular patterns 120 and 130 including their respective fingers are not in electrical contact with each other. Connection points 121 and 131 are provided for electrically connecting to the inner and outer circular patterns 120 and 130, respectively.

As would be appreciated by those skilled in the art, numerous alternatives to the etched metal portions may be practiced using any suitable electrically conducting elements, such as metal pins, rails or wires mounted on the PCB 110 or supported by a plastic molding or other support structure. The individual electrically conductive elements may be interconnected by wire or another suitable conductive medium.

In operation, at least one electrically conductive connecting member (not shown in FIG. 1), typically a ball is adapted to traverse the two concentric circular patterns 120 and 130 by way of a race, such as a circular groove or sidewalk. During traversal, the connecting member may be in contact with: an electrically conductive finger of the inner circular pattern 120, an electrically conductive finger of the outer circular pattern 130, an electrically conductive finger of both the inner and outer circular patterns 120 and 130 or not be in contact with an electrically conductive finger of either the inner or outer circular patterns 120 and 130. When the connecting member is in contact with an electrically conductive finger of both the inner and outer circular patterns 120 and 130, the connection points 121 and 131 are electrically connected. Otherwise, the connection points 121 and 131 are not electrically connected.

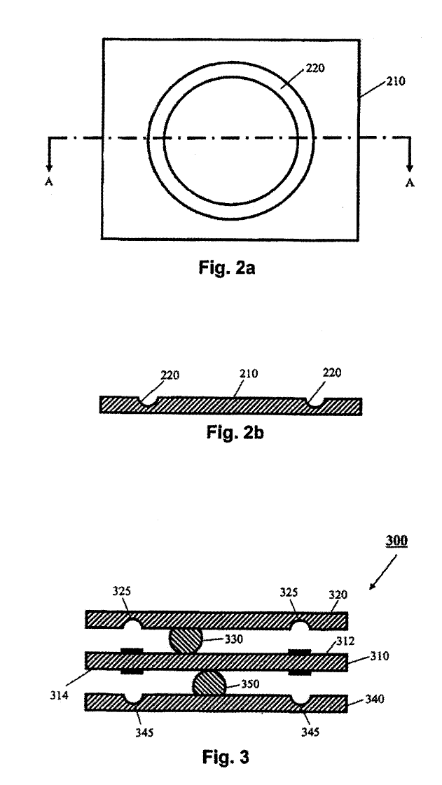

FIGS. 2A and 2B are a cover 210 for a motion sensor, which includes a circular groove 220 that provides a race for traversal by a connecting member. The cover may be produced as an injection-molded plastic component or may be made of another non-conductive material such as an acrylic polymer made by any methods known in the art, for example.

FIG. 3 is an exploded sectional front elevation of a motion sensor assembly 300. The motion sensor assembly 300 includes a PCB 310 sandwiched between upper and lower covers 320 and 340, respectively. The PCB 310 may be identical or substantially similar to the PCB 110 described with reference to FIG. 1A. The upper and lower covers 320 and 340 may be identical or substantially similar to the cover 210 described with reference to FIGS. 2A and 2B.

The motion sensor assembly 300 further includes 2 connecting members 330 and 350 produced from an electrically conductive material (e.g., balls from a ball bearing) that are free to traverse the circular grooves 325 and 345, respectively, in response to external stimuli such as an impact or a change in orientation of the motion sensor assembly 300. The connecting members 330 and 350 are constrained from leaving the circular grooves 325 and 345 by the upper and lower covers 320 and 340. The PCB 310 and the upper and lower covers 320 and 340 are spaced apart to accommodate the connecting members 330 and 350 such that when the connecting members 330 and 350 rest on a lower surface (i.e., the PCB 310 and the lower cover 340), a small gap exists between the connecting members 330 and 350 and a respective upper surface (i.e., the upper cover 320 and the PCB 310).

With the specific orientation of the motion sensor assembly 300 shown in FIG. 3, the connecting member 330 constrained to traverse the circular groove 325 is operational to provide an electrical connection between electrically conducting elements on the topside 312 of the PCB 310. As the orientation of the motion sensor assembly 300 is varied, the connecting member 330 traverses the circular groove 325 and, in doing so, causes different ones of the electrically conducting elements on the topside 312 of the PCB 310 to become electrically connected. Meanwhile, the connecting member 350 is inactive in that it is not in contact with the underside 314 of the PCB 310 and thus does not provide an electrical connection between electrically conducting elements on the underside 314 of the PCB 310.

When the motion sensor assembly 300 as shown in FIG. 3 is inverted, the connecting member 350 becomes operational to provide an electrical connection between electrically conducting elements on the underside of the PCB 310 and the connecting member 330 becomes inactive. Thus, only one of the connecting members 330 and 350 are operational at any one time and the motion sensor assembly 300 is capable of operation in any orientation.

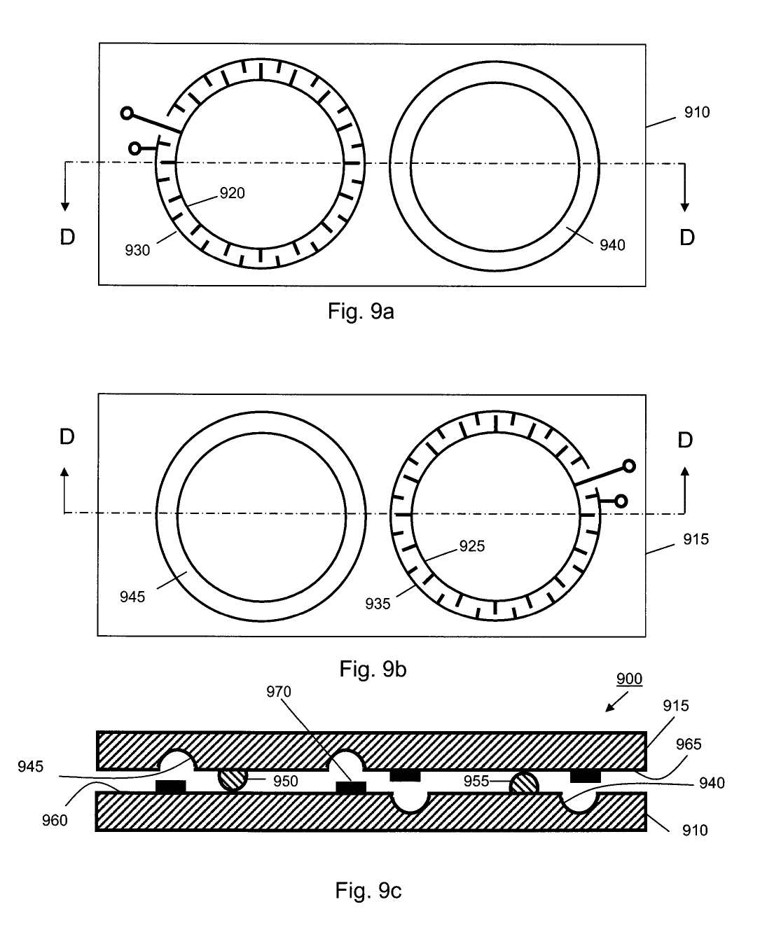

FIGS. 9A, 9B and 9C together illustrate a motion sensor assembly 900. The assembly 900 is similar in operation to motion sensor assembly 300 shown in FIG. 3, but with the added advantage that the arrangement shown in FIG. 9 has considerably reduced thickness.

The PCB 910 includes two circular patterns 920 and 930 of etched metal (e.g. copper) portions disposed on a planar surface of the PCB 910 and produced by a conventional PCB etching process as well as a circular groove 940 that provides a race for another conductive ball. PCB 915 complements PCB 910, so that the two can be placed in a face to face arrangement, in combination with connecting members 950 and 955, to construct motion sensor assembly 900.

FIG. 9C is a sectional view of the assembled motion sensor assembly 900 comprising PCB 910, PCB 915 and conductive balls 950 and 955 that are free to traverse the circular grooves 940 and 945. The connecting members 950 and 955 are constrained from leaving the circular grooves 945 and 945 by the PCBs 910 and 915, respectively. The PCBs 910 and 915 are spaced apart to accommodate the connecting members 950 and 955 such that when the connecting members 950 and 955 rest on the inward-facing surface of the lower PCB, a small gap exists between the connecting members 950 and 955 and the inward-facing surface of the upper PCB. The electrical elements are shown as 970.

With the specific orientation of the motion sensor assembly 900 shown in FIG. 9C, the connecting member 950 constrained to traverse the circular groove 945 is operational to provide an electrical connection between electrically conducting elements on the inward-facing side 960 of the PCB 910. As the orientation of the motion sensor assembly 900 is varied, the connecting member 950 traverses the circular groove 945 and, in doing so, causes different ones of the electrically conducting elements on the inward-facing side 960 of the PCB 910 to become electrically connected. Meanwhile, the connecting member 955 is inactive in that it is not in contact with the inward-facing side 965 of the PCB 915 and thus does not provide an electrical connection between electrically conducting elements on the inward-facing side 965 of the PCB 915.

When the motion sensor assembly 900 as shown in FIG. 9C is inverted, the connecting member 955 becomes operational to provide an electrical connection between electrically conducting elements on the inward-facing side of the PCB 915 and the connecting member 950 becomes inactive. Thus, only one of the connecting members 950 and 955 are operational at any one time and the motion sensor assembly 900 is capable of operation in any orientation.

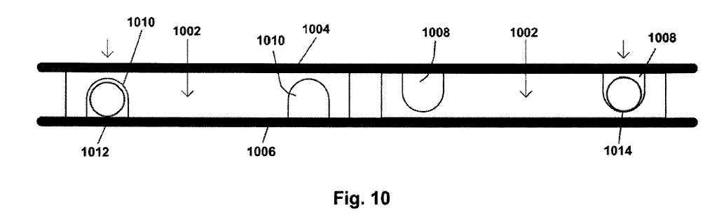

Another view of an embodiment with two motion sensors in side by side arrangement and sandwiched between opposing printed circuit boards is demonstrated in FIG. 10. A guide 1002 between the upper PCB 1004 and the lower PCB 1006 forms races 1008 and 1010. As can be seen, in the motion sensor on the left, in which the race is formed in the lower PCB, the ball 1012 rests on the electrical connectors on the face of the board, but there is a gap between the ball 1014 and the connectors in the sensor on the right side.

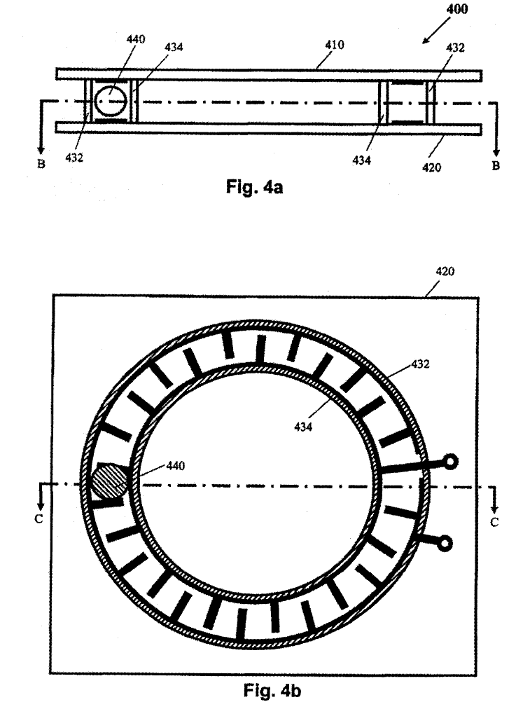

FIGS. 4A and 4B show a sectional front view and a sectional top view taken across sections ‘C-C’ and ‘B-B’, respectively, of a motion sensor 400. The motion sensor 400 includes two PCBs 410 and 420, which may be identical or substantially similar to the PCB 110 described with reference to FIG. 1. The PCBs 410 and 420 are spaced apart by circular spacers 431, 432, 433 and 434 to form a circular channel for the connecting member 440 to move within in response to external stimuli such as an impact or a variation in the orientation of the motion sensor 400. The PCBs are spaced apart sufficiently such that the connecting member 440 makes contact with only one of the PCBs 410 and 420 at any one time. Operation of the motion sensor 400 is substantially similar to that of the motion sensor assembly 300 described hereinbefore in that, as the connecting member 440 moves in response to external stimuli applied to the motion sensor 400, the connecting member 440 causes different ones of the electrically conducting elements on one of the PCBs 410 and 420 to become electrically connected. An advantage of the embodiment shown in FIG. 4 is that inverted operation of the motion sensor 400 using only one connecting member is possible.

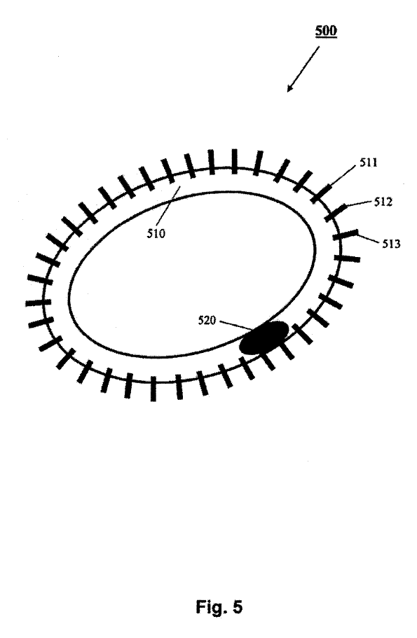

FIG. 5 shows a perspective view of a motion sensor 500. The motion sensor 500 includes a tube 510, for example, produced from glass or plastic. Electrically conductive elements 511, 512, 513, . . . , such as pins, contact surfaces or switches are disposed at intervals along the tube 510 and may be interconnected as required (e.g., alternately, as per the embodiments shown in FIGS. 1A and 4B) using wires or an alternative electrically conductive medium. The electrically conductive elements 511, 512, 513, . . . may be positioned during a glass or plastic molding process. A portion of an electrically conductive material 520, such as mercury, is disposed within the tube 510 and moves around the tube 510 in response to external stimuli applied to the tube 510, for example, an impact or a variation in the orientation of the tube 510. In doing so, the portion of electrically conductive material 520 provides an electrical connection between at least two of the electrically conductive elements 511, 512, 513.

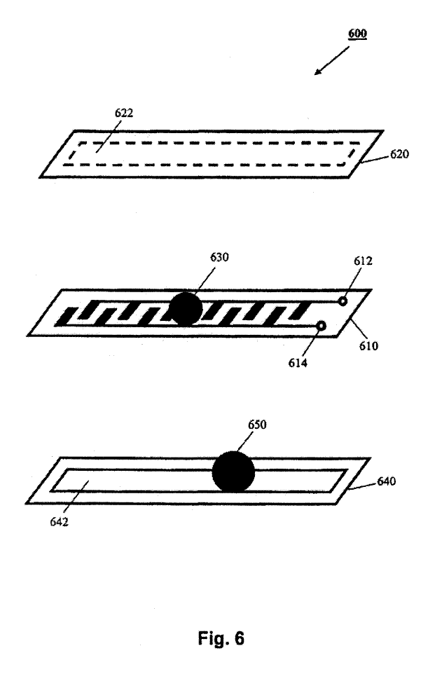

FIG. 6 shows an exploded perspective view of a motion sensor assembly 600. The motion sensor assembly 600 includes a PCB 610 sandwiched between upper and lower covers 620 and 640, respectively. The PCB 610 is similar to the PCB 110 described with reference to FIG. 1A, but is linear rather than circular in shape. The upper and lower covers 620 and 640 are similar to the cover 210 described with reference to FIGS. 2A and 2B, but are also linear rather than circular in shape. The motion sensor assembly 600 further includes two connecting members 630 and 650 5 that are identical or substantially similar to the connecting members 330 and 350 described with reference to FIG. 3. Operation of the motion sensor assembly 600 is substantially similar to the of the motion sensor assembly 300 described hereinbefore.

In another 3-dimensional embodiment, the motion sensor includes concentric spheres with electrically conductive elements on the inner surface of the outer sphere that are electrically connected by the inner sphere acting as a connecting member.

The motion sensors described herein are integrated with an electronic controller to provide an apparatus for detecting movement. The electronic controller typically includes a microprocessor or microcontroller, an alerting means such as an audible or visual alarm and a battery or other power source. As would be appreciated by those skilled in the art, the electronic controller may alternatively include an electronic circuit comprising discrete electronic components.

The electronic controller is electrically coupled to the electrically conductive elements that form part of the race/s of the motion sensor and activates the alerting means in response to external stimuli detected by the motion detector.

In certain embodiments, alternate ones of the electrically conductive elements are electrically connected together to form two sets of electrical contacts, which are each coupled to an input port of the microprocessor or microcontroller. Traversal of the connecting member connects and disconnects the two sets of electrically conductive elements, which is detected by the microprocessor or microcontroller.

In other embodiments, groups of the electrically connected conductive elements or each of the electrically conductive elements are electrically coupled to input ports of the microprocessor or microcontroller. This enables the microprocessor or microcontroller to determine the direction of traversal of the connecting member and/or the position of the connecting member on the race. Reference positions of the connecting member on the race may also be stored for detection of relative movement.

A range of sensitivity settings enables the alerting means to be activated in response to detection of external stimuli of magnitude greater than a predefined level. Arming and disarming of the alerting means may, for example, be performed by entry of a PIN-code via a keypad into the electronic controller.

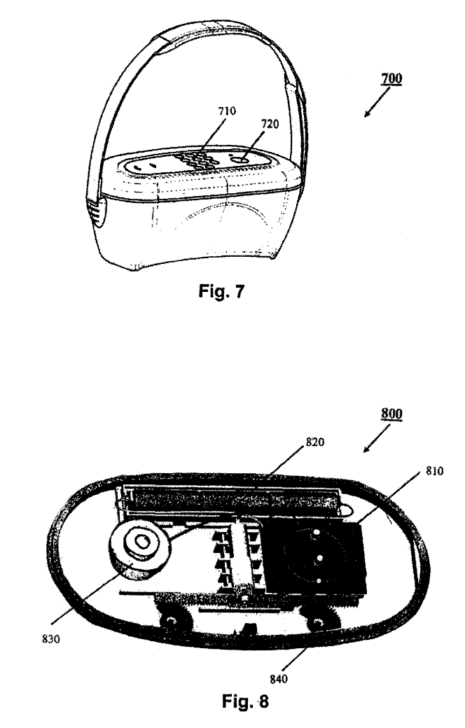

FIG. 7 shows a secure portable container 700 that incorporates a motion sensor as described herein in accordance with an embodiment of the present invention. The secure portable container further includes a numeric keypad 710 for entry of a PIN-code to lock and unlock the secure portable container 700 and/or to arm and disarm an audible alarm 720.

FIG. 8 shows the underside of the lid 800 of the secure portable container 700 of FIG. 7, which includes a motion sensor 810 as described hereinbefore in accordance with an embodiment of the present invention, an audible alarm 830, a battery pack 820 and a locking mechanism 840.

One application of the secure portable storage container of FIGS. 7 and 8 is for storing personal items such as car keys, mobile telephones, wallets and purses outdoors and at the beach. Detection of movement of the container while an alarm integrated with the container is armed results in activation of the alarm, thus alerting the owner of the container of a possible theft.

Embodiments of the motion sensors described herein can be integrated with a wide variety of objects to provide an indication of movement of such objects. This advantageously prevents or at least reduces the likelihood of theft or tampering with the object. Examples of objects with which the apparatus for detecting movement may be integrated include, but are not limited to: general containers, tool boxes, lockers, cupboard doors, cooler boxes (eskys), box trailers, boat trailers, boats, motor bikes, push bikes, utility vehicle lids and toolboxes, caravans, display cabinets, portable computers, briefcases, suitcases, designer clothes and handbags, backpacks, and sports bags.

Alternatively, a linear motion sensor such as that described with reference to FIG. 6 may be employed to produce a digital spirit level, a square and/or a “T” square.

The preceding description provides exemplary embodiments only, and is not intended to limit the scope, applicability or configurations of the invention. Rather, the description of the exemplary embodiments provides those skilled in the art with enabling descriptions for implementing an embodiment of the invention. Various changes may be made in the function and arrangement of elements without departing from the spirit and scope of the invention as set forth in the claims. Where specific features and/or elements referred to herein have known equivalents in the art to which the invention relates, such known equivalents are deemed to be incorporated herein as if individually set forth. Furthermore, features and/or elements referred to in respect of particular embodiments may optionally form part of any of the other embodiments unless stated to the contrary.

1. A motion sensor assembly comprising:
a central planar member having a top side and a bottom side,
a first motion sensor apparatus on the top side of the central planar member and a second motion sensor apparatus on the bottom side of the central planar member; wherein each motion sensor apparatus comprises:
concentric rings of interdigitated electrical connection elements, comprising an outer ring of inner projecting connection elements and an inner ring of outer projecting connection elements, wherein the inner ring and outer ring form one or more complete electric circuits open by the space between interdigitated elements;
an electrically conductive ball sized to contact adjacent electrical connection elements and to complete an electrical circuit when in contact with adjacent elements; and
electrical connectors configured to connect the electrical connection elements to a microprocessor.

2. The motion sensor assembly of claim 1, comprising a pair of covers, one fitted to each face of the central planar member, wherein each cover provides a race for one of said balls.

3. The motion sensor assembly of claim 1, wherein the central planar member is a printed circuit board.

4. A motion sensor device comprising:
a pair of printed circuit boards spaced apart in parallel orientation wherein a pair of motion sensor assemblies are disposed side by side between the facing sides of the printed circuit boards, and wherein each printed circuit board comprises a ring of interdigitated electrical connection elements, wherein the ring comprises an outer ring of inner projecting connection elements and an inner ring of outer projecting connection elements, wherein the inner ring and outer ring form one or more complete electric circuits open by the space between interdigitated elements;
a guide disposed between the printed circuit boards, connecting the printed circuit boards in parallel orientation such that the ring of the first printed circuit board is spaced laterally from the ring on the second printed circuit board such that the ring of each printed circuit board is opposed to a space on the opposite printed circuit board that does not include a ring;
wherein the guide provides at least a portion of a pair of races, one disposed over each ring, wherein the races are configured as tunnels having an open floor surface and a closed top surface, and where each ring forms the floor surface of a race;
an electrically conductive ball contained in each race and sized to contact adjacent interdigitated elements and to close the electrical circuits when in contact with adjacent interdigitated elements and sized to be constrained within the race and to freely move through the race and further sized such that when the ball is in contact with the top of the race, the ball does not contact the electrical connection elements on the bottom surface of the race.
